(19) United States
(12) Patent Application Publication
(10) Pub. No.: US 2018/0226220 A1
(43) Pub. Date: Aug. 9, 2018

(54) CONTINUOUSLY VARIABLE APERTURE

(71) Applicant: Howard Hughes Medical Institute, Chevy Chase, MD (US)

(72) Inventors: Tamir Gonen, Ashburn, VA (US); Igor Negrashov, Leesburg, VA (US); Dan Shi, Ashburn, VA (US); Tanya Tabachnik, New York, NY (US)

(21) Appl. No.: 15/867,275

(22) Filed: Jan. 10, 2018

Related U.S. Application Data
(60) Provisional application No. 62/446,376, filed on Jan. 14, 2017.

(51) Int. Cl. H01J 37/15; H01J 37/18; H01J 37/26; H01J 37/10

(52) U.S. Cl. CPC H01J 37/15; H01J 37/18; H01J 37/265; H01J 2237/1502; H01J 2237/0492; H01J 2237/063; H01J 37/10

(57) ABSTRACT

An apparatus for a transmission electron microscope includes a housing configured to be attached to the transmission electron microscope; a plunger received in the housing and movable relative to the housing; a first set of pieces coupled to the plunger, the first piece being configured to move relative to the housing in response to the plunger moving relative to the housing; and a second set of pieces positioned in a fixed spatial relationship relative to each other, the second set of pieces and the first set of pieces forming a perimeter of an opening, an extent of the opening being continuously variable by moving the first set of piece relative to the second set of pieces.

### CROSS-REFERENCE TO RELATED APPLICATION

This application claims the benefit of U.S. Provisional Application No. 62/446,376, filed on Jan. 14, 2017 and titled CONTINUOUSLY VARIABLE APERTURE, which is incorporated herein by reference in its entirety.

### TECHNICAL FIELD

This disclosure relates to a continuously variable aperture.

### SUMMARY

In one general aspect, an apparatus for a transmission electron microscope includes a housing configured to be attached to the transmission electron microscope; a plunger received in the housing and movable relative to the housing; a first piece coupled to the plunger, the first piece being configured to move relative to the housing in response to the plunger moving relative to the housing; a second piece; and a third piece angled relative to the second piece, the first, second, and third pieces being arranged relative to each other to form a triangularly shaped opening.

Implementations can include one or more of the following features. An extent of the triangularly shaped opening can be variable by moving the first piece relative to the second and third pieces. The extent of the triangularly shaped opening can be variable between 5 and 200 microns (μm). The extent of the triangular shaped opening can be variable between 0 and 2000 microns (μm).

The housing can be attached to the transmission electron microscope, and the triangularly shaped opening can be in a plane that is perpendicular to a direction of travel of an electron beam of the transmission electron microscope. The first, second, and third pieces can be physically separated from each other along a direction that is parallel to the direction of travel of the electron beam. The housing can be configured to attach to the transmission electron microscope by being mounted in a sidewall of a vacuum chamber of the transmission electron microscope.

The apparatus can include a micrometer coupled to the plunger. Manipulation of the micrometer can cause the plunger and the first piece to move relative to the housing.

The second and third pieces can be held in a fixed spatial relationship to each other. The second and third pieces can be held in a fixed spatial relationship relative to the housing. The second and third pieces can remain stationary when the plunger moves relative to the housing. The second and third pieces can be held at fixed an angle relative to each other.

In some implementations, the first piece is positioned at a first angle relative to the second piece and at a second angle relative to the third piece, and the second and third pieces are positioned at a third angle relative to each other. The first angle, the second angle, and the third angle can be the same.

Each of the first, second, and third pieces can be a non-magnetic material.

In another general aspect, a transmission electron microscope includes a vacuum chamber; a source configured to emit a beam of electrons onto a beam path that is inside the vacuum chamber; a mount configured to receive a specimen, at least a portion of the mount being in the beam path; and a continuously variable aperture assembly mounted to the housing. The continuously variable aperture assembly includes a housing configured to be mounted through a sidewall of the vacuum chamber; a plunger received in the housing and movable relative to the housing; a first piece coupled to the plunger, the first piece being configured to move relative to the housing in response to the plunger moving relative to the housing; a second piece; and a third piece angled relative to the second piece, the first, second, and third pieces being arranged relative to each other to form a triangularly shaped opening.

In some implementations, the housing is mounted through the sidewall of the vacuum chamber, the triangularly shaped opening is in a plane that intersects the beam path and is perpendicular to a direction of travel of the electron beam.

In another general aspect, an apparatus for a transmission electron microscope includes a housing configured to be attached to the transmission electron microscope; a plunger received in the housing and movable relative to the housing; a first set of pieces coupled to the plunger, the first piece being configured to move relative to the housing in response to the plunger moving relative to the housing; and a second set of pieces positioned in a fixed spatial relationship relative to each other, the second set of pieces and the first set of pieces forming a perimeter of an opening, an extent of the opening being continuously variable by moving the first set of piece relative to the second set of pieces.

Implementations can include one or more of the following features. The opening can have an approximately circular shape at least at some relative positions of the first set of pieces and the second set of pieces. The first set of pieces can be a single piece.

Implementations can include a continuously variable aperture assembly, a continuously variable aperture, a method, an apparatus, a system, or a computer-readable medium including executable instructions.

### DRAWING DESCRIPTION

FIG. 1 is a block diagram of a transmission electron microscope that includes an exemplary continuously variable aperture assembly.

FIGS. 2A and 2B are top views of an aperture of the continuously variable aperture assembly of FIG. 1.

FIG. 2C is a side view of the aperture of FIGS. 2A and 2B.

FIG. 3A is a perspective view of another exemplary continuously variable aperture assembly.

FIG. 3B is a side view of the continuously variable aperture assembly of FIG. 3A.

FIG. 3C is a side cross-sectional view of the continuously variable aperture assembly taken along line C-C of FIG. 3A.

FIG. 3D is a top view of an aperture of the continuously variable aperture assembly of FIG. 3A.

FIG. 3E is a partial view of a plunger of the continuously variable aperture assembly of FIG. 3A.

FIG. 3F is a cross-sectional top view of an exemplary opening of the continuously variable aperture assembly 3A.

### DETAILED DESCRIPTION

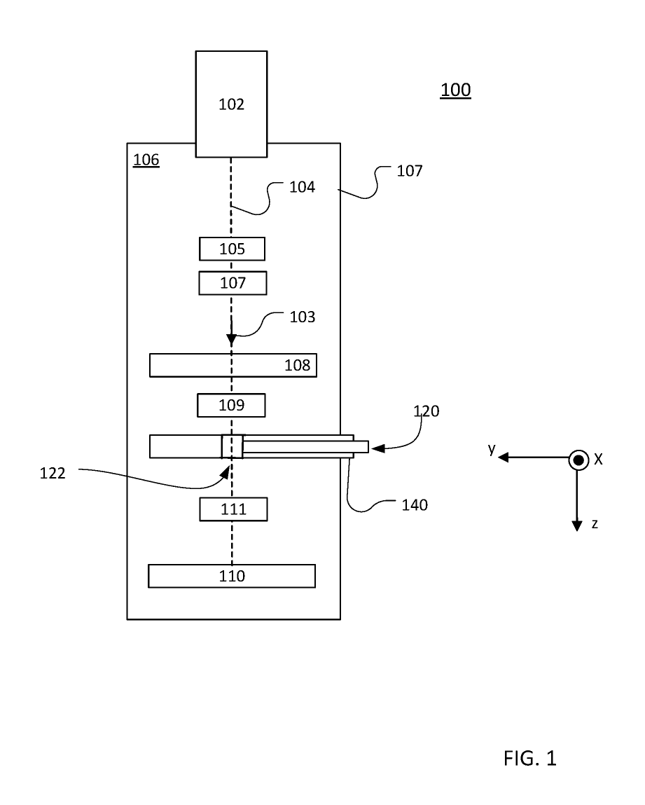

Referring to FIG. 1, a transmission electron microscope (TEM) 100 that includes a continuously variable aperture assembly 120 is shown. As discussed below, the continuously variable aperture assembly 120 includes an aperture 122 that has an extent or size that is continuously variable. The TEM 100 includes an electron beam generator 102 that emits an electron beam 103 that travels in a z direction along a beam path 104 in a vacuum chamber 106. The electron beam 103 is transmitted through and interacts with a specimen 108. For example, the electron beam 103 can be absorbed and/or scattered by the specimen 108. The interaction between the electron beam 103 and the specimen 108 forms an image and/or a diffraction pattern of the specimen 108 that is detected by a detector 110. Data from the detector 110 can be used to form an image of the specimen 108.

The continuously variable aperture assembly 120 includes an aperture 122, the size of which can be continuously adjusted during use. By being continuously adjustable, the size of the aperture 122 can be varied to be any value between a minimum aperture size, for example, 5 microns (μm), and a maximum aperture size, for example, 100 μm. In some implementations, the minimum aperture size may be 0 μm such that the aperture 122 may be closed to block the electron beam 103. The variable aperture size allows control of the dose or amount of the electron beam 103 that reaches the specimen 108. The variable size of the aperture 122 may allow, for example, radiation damage of the specimen 108 to be minimized or avoided.

The continuous variable aperture assembly 120 is in contrast to some TEM systems, which can include a finite set of apertures, for example, four apertures, that each have a different fixed aperture size. The limited number of sizes and the process of switching between the limited apertures available for selection can pose challenges in data collection and data quality.

The continuously variable aperture assembly 120 with the continuously variable aperture 122 allows the TEM 100 to be used for general applications that require a wider selection of aperture sizes. Additionally, the size of the continuously variable aperture 122 can be varied during use and, thus, without dropping the vacuum on the TEM 100 and without interfering with data collection and/or use of the TEM 100. As such, the size of the aperture 122 can be varied by any operator of the TEM 100 through a safe and simple procedure.

The TEM 100 also includes other components, such as condenser lens assembly 105, deflection coils 107, an objective lens assembly 109, and a projection lens assembly 111, to direct and control the electron beam 103 and the image detected by the detector 110. The condenser lens assembly 105 and the objective lens assembly 109 include apertures. The aperture of the condenser lens assembly 105 controls the size of the electron beam 103, and the aperture of the objective lens assembly 109 controls the spatial resolution.

The TEM 100 also can include a diffraction lens assembly that controls the area from which the diffraction pattern of the specimen 108 is generated. In the example shown, the continuously variable aperture assembly 120 is positioned such that the continuously variable aperture 122 is in the position where an aperture of the diffraction lens assembly otherwise would be. Thus, the size of the continuously variable aperture 122 controls the area from which the diffraction pattern of the specimen 108 is generated.

Controlling the area from with the diffraction pattern is generated with the aperture 122 allows the operator of the TEM 100 to select particular areas of the specimen 108 to study. For example, the specimen 108 can include crystals that vary in size and/or shape. Having an aperture with a size that is close in size to the crystal of interest and not bigger or smaller than the crystal of interest can enhance the data collected for that crystal. Thus, the variable aperture 122 can allow the area from which the diffraction pattern is generated to be varied and set according to a particular crystal during operation of the TEM 100. This can improve the observation of the crystals and also can reduce the amount of time required for data collection.

Although in the example shown in FIG. 1 the aperture 122 is positioned to control the area from which the diffraction pattern is generated, the aperture 122 formed by the continuously variable aperture assembly 120 can be used for any aperture of the TEM 100. For example, the aperture 122 can be used at the location of the aperture of the condenser lens assembly 105 to improve the quality of the data produced by the TEM 100.

The aperture assembly 120 also includes a housing 140 that is mounted through a side wall 107 of the vacuum chamber 106. The housing 140 includes a mount that allows the housing 140 and the continuously variable aperture assembly 120 to be held in the side wall 107 with a vacuum seal.

As discussed in greater detail below, the aperture 122 forms an opening or region in an x-y plane (perpendicular to the z direction). Thus, the aperture 122 presents an opening or region, the size of which can be continuously varied, to the electron beam 103. Moreover, the opening or region may be closed to block the electron beam 103. In the discussion below, the aperture 122 is formed from three blades 125a, 125b, and 125c, and the aperture 122 has an opening 123 with a triangular shape. However, the aperture 122 can take other forms. For example, the aperture 122 can have more than three blades that are arranged relative to each other to provide an opening that is a shape other than a triangle, such as a square, rectangle, or a shape that is similar to a circle.

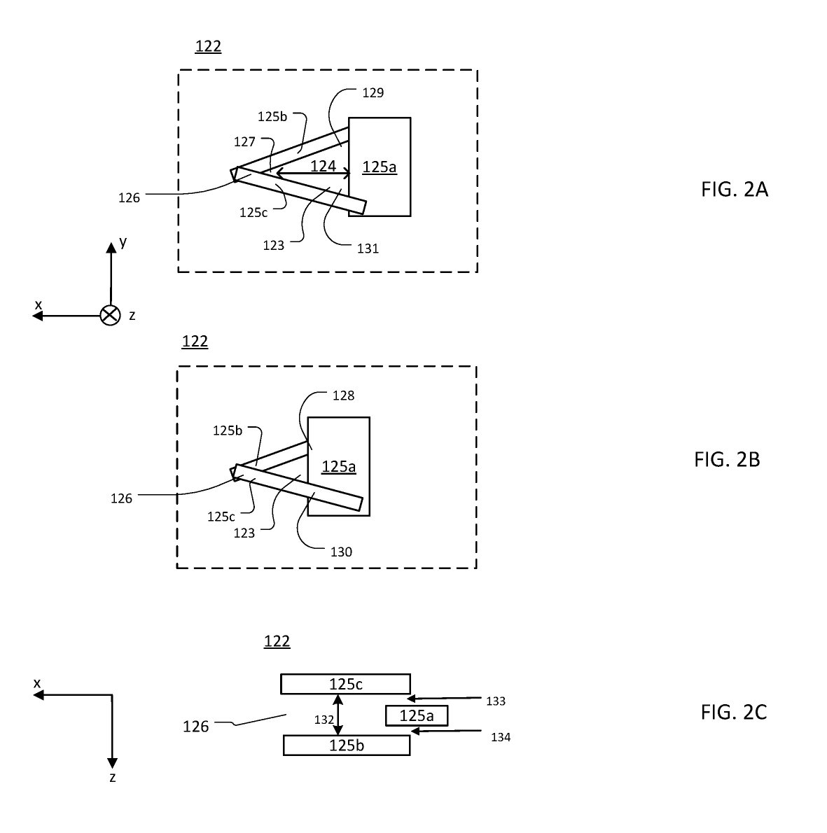

Referring also to FIGS. 2A and 2B, top views of the aperture 122 of the continuously variable aperture assembly 120 are shown. The aperture 122 includes blades 125a, 125b, and 125c. The ends of the blades 125a, 125b, and 125c are overlapped or stacked relative to each other in the z direction to form a triangularly shaped opening 123 having a variable extent 124 in the x direction. The opening 123 is in an x-y plane that is perpendicular to the z direction in which the electron beam 103 travels. Thus, the aperture 122 can be used to block a portion or all of the electron beam 103 while allowing some of the electron beam 103 to pass. Because the extent 124 is variable, when the aperture 122 is positioned in the TEM 100 as shown in FIG. 1, the aperture 122 can be used to control the area from which the diffraction pattern is generated.

In the example shown in FIGS. 2A and 2B, the blades 125b and 125c overlap at a location 126 and form an angle 127, the blades 125a and 125b overlap at a location 128 (FIG. 2B) and form an angle 129, and the blades 125a and 125c overlap at a location 130 and form an angle 131. The angles 127, 129, and 131 can have any value such that the opening 123 has a triangle shape. For example, the angles 127, 129, and 131 can be 60 degrees (°).

In the example shown, the extent 124 is the distance in the x direction from the location 126 to a side 135 of the blade 125a that is closest to the location 126. The aperture 122 is a variable aperture because the extent 124 can be adjusted by moving the blade 125a in the x direction relative to the location 126. For example, as shown in FIG. 2B, the extent 124 can be reduced by moving the blade 125a closer to the location 126. The extent 124 can be increased by moving the blade 125a away from the location 126. The extent 124 can be varied between, for example, 0 μm and 2000 μm such that, the aperture 122 can be varied between a closed state (with the extent at 0 μm) in which the electron beam 103 is blocked and does not reach the specimen 108, and an open state in which the electron beam 103 is not blocked.

Referring also to FIG. 2C, which shows a side view of the aperture 122, although the blades 125a, 125b, and 125c are stacked in the z direction to form the perimeter of the opening 123, the blades 125a, 125b, and 125c can be physically separated from each other. In the example shown in FIG. 2C, the blades 125c and 125b are separated in the z direction by a distance 132, the blades 125c and 125a are separated in the z direction by a distance 133, and the blades 125a and 125b are separated in the z direction by a distance 134. The distances 133 and 134 can be, for example, 0.2-0.3 millimeters (mm).

In the example of FIGS. 2A-2C, the extent 124 is varied by moving the blade 125a relative to the blades 125b and 125c in the x direction. In other examples, the extent 124 can be varied by moving any of the blades 125a, 125b, and 125c relative to the other blades in the x and/or y directions. Additionally or alternatively, more than one of the blades 125a, 125b, and 125c can be moved to change the extent 124. For example, the blades 125b and 125c can be moved in the x direction while the blade 125 is stationary.

The blades 125a, 125b, and 125c can be made of any non-magnetic metal that is chemically stable and has good thermal and electrical conductivity. For example, the blades 125a, 125b, and 125c can be made of copper, gold, or an alloy that includes these or other materials.

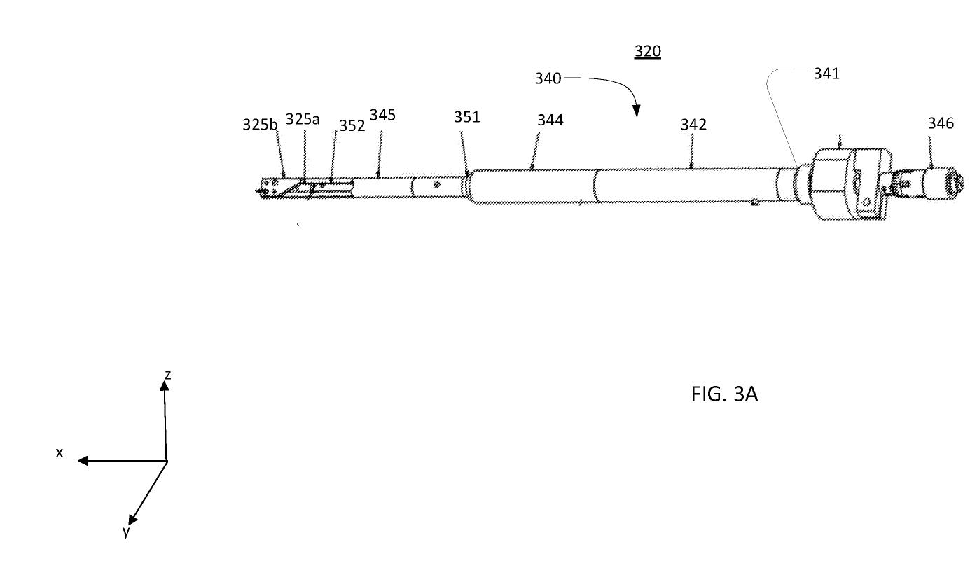

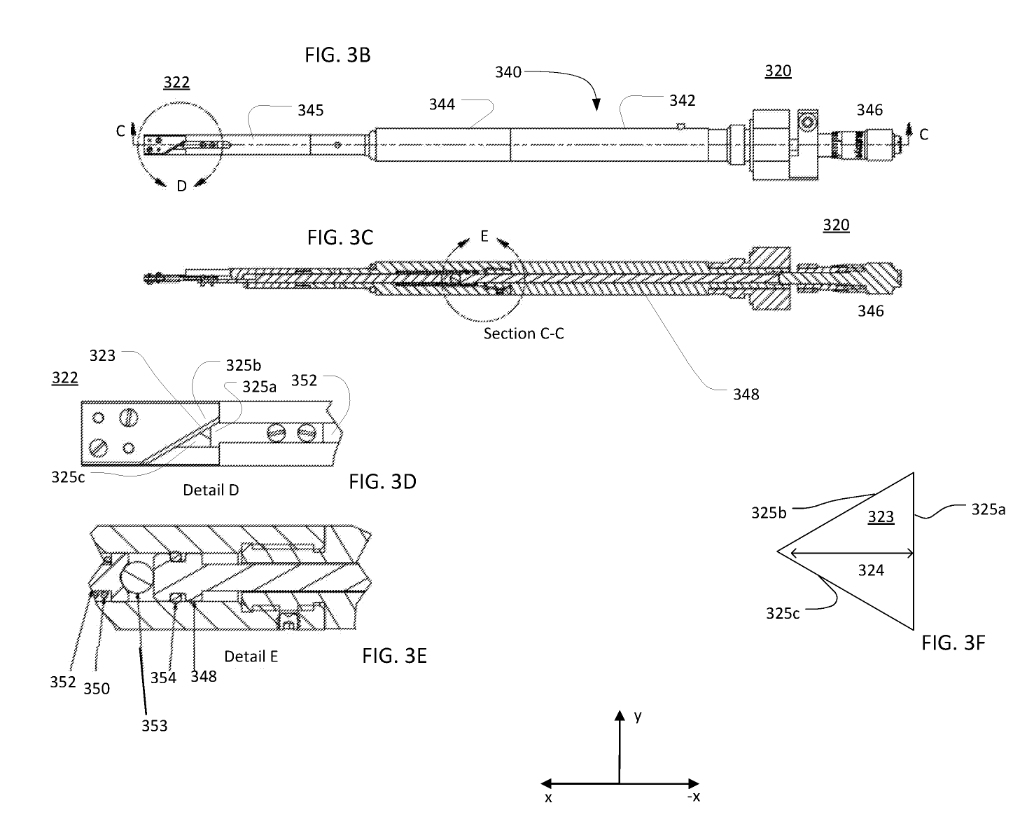

Referring to FIGS. 3A-3F, an exemplary continuously variable aperture assembly 320 is shown. FIG. 3A shows a perspective view of the continuously variable aperture assembly 320, FIG. 3B shows a side plan view of the continuously variable aperture assembly 320, and FIG. 3C shows a cross-sectional view of the continuously variable aperture assembly 320. FIG. 3D shows a detailed top view of the aperture 322 and opening 323. FIG. 3E shows a partial view of a plunger assembly that is used to adjust the extent 324. FIG. 3F shows a cross-sectional view of the opening 323.

The continuously variable aperture assembly 320 can be used in the TEM 100 or in any other transmission electron microscope. The continuously variable aperture assembly 320 includes the aperture 322, which has the triangularly shaped opening 323 with the variable extent 324. When the continuously variable aperture assembly 320 is mounted to the microscope (for example, through the side wall 107 of the TEM 100), the opening 323 is perpendicular to the direction of travel of the electron beam 103.

The continuously variable aperture assembly 320 includes a housing 340 that includes a plunger holder 342, an O-ring holder 344, and a blade holder 345. The plunger holder 342 and the O-ring holder 344 are connected to the blade holder 345, and the plunger holder 342 receives a plunger 348 that is movable in the x direction relative to the plunger holder 342. The blade holder 345 receives a moving blade holder 352 that is movable in the x direction relative to the blade holder 345. The O-ring holder 344 includes an O-ring 351 to create vacuum seal with the chamber of the microscope

Referring also to FIG. 3D, the aperture 322 includes blades 325a, 325b, and 325c, which form the perimeter of the opening 323. The blades 325b, 325c, and blade holder 345 are held in a fixed relationship. For example, the blades 325b, 325c and blade holder 345 can be held in a fixed relationship to each other with screws. The angle between blades 325b and 325c can be, for example, 60°. The blade 325a is attached to the moving blade holder 352 and is movable relative to the blades 325b and 325c in the x direction.

As shown in FIG. 3E, the plunger 348 has an O-ring 354 that creates a vacuum seal inside the continuously variable aperture assembly 320. A spring 350 is between the O-ring holder 344 and the moving blade holder 352. The housing 340 is attached to a micrometer 346. The micrometer 346 is coupled to the plunger 348 such that, when the micrometer 346 is turned or otherwise manipulated, the plunger 348 moves relative to the plunger holder 342 in the x direction. The plunger 348 pushes the moving blade holder 352 in the x-direction through a ceramic ball 353, which creates flexible joint to accommodate fabrication tolerances. Pushing the moving blade holder 352 in the x direction compresses the spring 350. The spring 350 relaxes, moving the blade holder 352 back (in the −x direction) when micrometer 346 is adjusted back to its original position.

Because the blade 325a is attached to an end of the moving blade holder 352, the blade 325a moves in the x direction relative to the blades 325b and 325c when the moving blade holder 352 moves in the x direction. As such, moving the moving blade holder 352 in the x direction causes the extent 324 of the aperture 322 to decrease, and moving the blade holder 352 in the −x direction (opposite to the x direction) causes the extent 324 to increase. Thus, the extent 324 of the opening 323 can be adjusted with the micrometer 346 while the continuously variable aperture assembly 320 is positioned in the microscope.

Additionally, the housing 340 allows the assembly 320 to be mounted such that the micrometer 346 that is used to control the size of the extent 324 is positioned in a location that is accessible to an operator. For example, in a TEM, the micrometer 346 can be mounted on the outside of the vacuum chamber in which the electron beam propagates. In another example, the micrometer 346 can be mounted away from other components of the microscope to ensure that adjusting the extent 324 does not change the alignment or other settings of the microscope. In the example of FIGS. 3A-3E, the housing 340 includes threads 341 that can be used to attach the housing 340 to corresponding threads on a microscope housing.

Other implementations are within the scope of the claims. For example, the micrometer 346 can be manually adjusted by a human operator or automatically adjusted by a motor and/or actuator that is controlled by a computerized process. The continuously variable aperture assembly 120 or 320 can be used as an aperture in an apparatus that uses an electron beam other than a TEM. Additionally, the continuously variable aperture assembly 120 or 320 may be used as a variable aperture in a system that includes an irradiating or illuminating beam but is not necessarily a microscope.

What is claimed is:

1. An apparatus for a transmission electron microscope, the apparatus comprising:
a housing configured to be attached to the transmission electron microscope;
a plunger received in the housing and movable relative to the housing;
a first piece coupled to the plunger, the first piece being configured to move relative to the housing in response to the plunger moving relative to the housing;
a second piece; and
a third piece angled relative to the second piece, the first, second, and third pieces being arranged relative to each other to form a triangularly shaped opening.

2. The apparatus of claim 1, wherein an extent of the triangularly shaped opening is variable by moving the first piece relative to the second and third pieces.

3. The apparatus of claim 1, wherein, when the housing is attached to the transmission electron microscope, the triangularly shaped opening is in a plane that is perpendicular to a direction of travel of an electron beam of the transmission electron microscope.

4. The apparatus of claim 3, wherein the first, second, and third pieces are physically separated from each other along a direction that is parallel to the direction of travel of the electron beam.

5. The apparatus of claim 1, wherein the housing is configured to attach to the transmission electron microscope by being mounted in a sidewall of a vacuum chamber of the transmission electron microscope.

6. The apparatus of claim 1, wherein the extent of the triangular shaped opening is between 0 and 2000 microns (μm).

7. The apparatus of claim 2, further comprising a micrometer coupled to the plunger, and wherein manipulation of the micrometer causes the plunger and the first piece to move relative to the housing.

8. The apparatus of claim 1, wherein the second and third pieces are held in a fixed spatial relationship to each other.

9. The apparatus of claim 8, wherein the second and third pieces are held in a fixed spatial relationship relative to the housing.

10. The apparatus of claim 9, wherein the second and third pieces remain stationary when the plunger moves relative to the housing.

11. The apparatus of claim 8, wherein the second and third pieces are held at fixed an angle relative to each other.

12. The apparatus of claim 1, wherein:
the first piece is positioned at a first angle relative to the second piece and at a second angle relative to the third piece, and
the second and third pieces are positioned at a third angle relative to each other.

13. The apparatus of claim 12, wherein the first angle, the second angle, and the third angle are the same.

14. The apparatus of claim 1, wherein each of the first, second, and third pieces comprise a non-magnetic material.

15. The apparatus of claim 1, further comprising a micrometer coupled to the plunger, the plunger moving relative to the housing in response to manipulation of the micrometer.

16. A transmission electron microscope comprising:
a vacuum chamber;
a source configured to emit a beam of electrons onto a beam path that is inside the vacuum chamber;
a mount configured to receive a specimen, at least a portion of the mount being in the beam path; and
a continuously variable aperture assembly mounted to the housing, the continuously variable aperture assembly comprising:
a housing configured to be mounted through a sidewall of the vacuum chamber;
a plunger received in the housing and movable relative to the housing;
a first piece coupled to the plunger, the first piece being configured to move relative to the housing in response to the plunger moving relative to the housing;
a second piece; and
a third piece angled relative to the second piece, the first, second, and third pieces being arranged relative to each other to form a triangularly shaped opening.

17. The transmission electron microscope of claim 16, wherein, when the housing is mounted through the sidewall of the vacuum chamber, the triangularly shaped opening is in a plane that intersects the beam path and is perpendicular to a direction of travel of the electron beam.

18. An apparatus for a transmission electron microscope, the apparatus comprising:
a housing configured to be attached to the transmission electron microscope;
a plunger received in the housing and movable relative to the housing;
a first set of pieces coupled to the plunger, the first piece being configured to move relative to the housing in response to the plunger moving relative to the housing; and
a second set of pieces positioned in a fixed spatial relationship relative to each other, the second set of pieces and the first set of pieces forming a perimeter of an opening, an extent of the opening being continuously variable by moving the first set of piece relative to the second set of pieces.

19. The apparatus of claim 18, wherein the opening has an approximately circular shape at least at some relative positions of the first set of pieces and the second set of pieces.

20. The apparatus of claim 18, wherein the extent of the opening is variable from between 0 and 2000 microns (μm).
